(19) United States
(12) Patent Application Publication
(10) Pub. No.: US 2007/0024313 A1
(43) Pub. Date: Feb. 1, 2007

(54) Chuck top, wafer holder having the chuck top, and wafer prober having the chuck top

(76) Inventors: Katsuhiro Itakura, Itami-shi (JP); Masuhiro Natsuhara, Itami-shi (JP); Tomoyuki Awazu, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/493,920

(22) Filed: Jul. 27, 2006

(30) Foreign Application Priority Data
Jul. 27, 2005 (JP) 2005-216699 (P)

(51) Int. Cl. G01R 31/26

(52) U.S. Cl. 324/765

(57) ABSTRACT

A chuck top allowing reliable recognition of a wafer mounted on a wafer-mounting surface or on a chuck top conductive layer by a camera such as a CCD and hence allowing wafer inspection without problem is provided. The chuck top is used for a wafer prober mounting a wafer on the wafer-mounting surface for inspection, in which reflectance of a portion other than the portion for mounting the wafer of the wafer-mounting surface or the chuck top conductive layer is smaller than the reflectance of a peripheral end portion of the wafer to be inspected. The portion other than the portion for mounting the wafer of the wafer-mounting surface or the chuck top conductive layer of chuck top preferably has surface roughness Ra of at least 0.0001 μm and at most 0.05 μm.

### BACKGROUND OF THE INVENTION

1. Field of the Invention

The present invention relates to a chuck top suitably used for a wafer prober for inspecting electric characteristics of a wafer, and to a wafer holder and a wafer prober including the chuck top.

2. Description of the Background Art

Conventionally, in a process for inspecting a semiconductor wafer, a semiconductor substrate (wafer) as an object of processing has been subjected to heat treatment. Specifically, burn-in is performed, in which by heating the wafer to a temperature higher than the normal temperature of use, degradation of a possibly defective semiconductor chip is accelerated and the defective chip is removed, in order to prevent defects after shipment. In the burn-in process, after semiconductor circuits are formed on the semiconductor wafer and before the wafer is cut into individual chips, electrical characteristics of each chip are measured while the wafer is heated and defective ones are removed. In the burn-in process, reduction of process time is strongly desired in order to improve throughput.

In the burn-in process as such, a heater holding the wafer for heating the wafer is used. As the conventional heater, one formed of metal has been used, because it is necessary to have the entire rear surface of the wafer in contact with the ground electrode. Specifically, on a flat plate heater formed of metal, the wafer having the circuits formed thereon is mounted and heated, and electric characteristics of the chip are measured

At the time of measurement, however, a prober referred to as a probe card having a number of electrode pins for electric conduction is pressed to the wafer with a force of several tens to several hundreds kgf, and therefore, when the heater is thin, the heater would possibly be deformed, resulting in contact failure between the wafer and the ground electrode. Therefore, it has been necessary to use a thick metal plate having the thickness of at least 15 mm for the heater, in order to maintain rigidity of the heater. As a result, it takes long time to increase and decrease the temperature of the heater, which is a significant drawback in improving the throughput.

In the burn-in process, the chip is electrically conducted and electric characteristics are measured. As recent chips come to have higher outputs, it is possible that a chip generates considerable heat during measurement of electric characteristics, and in some situations, the chip might be broken by self-heating. Therefore, after measurement, rapid cooling is required. During measurement, heating as uniform as possible is required. In view of the foregoing, copper (Cu) having thermal conductivity as high as 403 W/mK has been used as the metal material for the heater.

In consideration of such problems, Japanese Patent Laying-Open No. 2001-033484 proposes a wafer prober having a ceramic substrate that is thin but having high rigidity and is not susceptible to deformation with a thin metal layer formed on its surface, in place of the thick metal plate, to be less susceptible to deformation and to have smaller thermal capacity. It is described that the wafer prober having the metal layer formed on the surface of the ceramic substrate has high rigidity and therefore it does not cause contact failure, and as it has small thermal capacity, it allows heating and cooling of the wafer in a short period of time. It is described that as a support base for mounting the wafer prober, an aluminum alloy or stainless steel may be used.

### SUMMARY OF THE INVENTION

Generally, when inspection of the wafer having minute interconnections formed thereon is performed in the manner as described above, it is necessary to recognize the position of the wafer and register accurately, so that the prober is pressed to a prescribed position of the wafer. State of the art technique uses a camera such as a CCD to recognize the wafer position for registration.

Conventional wafer probers including the wafer prober using the ceramic substrate described in Japanese Patent Laying-Open No. 2001-033484 mentioned above have a wafer-mounting surface or a chuck top conductive layer formed of metal, in order to secure conduction to the wafer. Therefore, it has been difficult on a conventional chuck top to recognize the wafer by a camera such as a CCD, which possibly leads to a probing failure.

In view of the foregoing, an object of the present invention is to provide a chuck top allowing reliable recognition of a wafer mounted on a wafer-mounting surface or a chuck top conductive layer by a camera such as a CCD and thereby allowing wafer inspection without any problem, as well as to provide a wafer holder and a wafer prober including the chuck top.

In order to attain the above-described object, the present invention provides a chuck top preferably used for a wafer prober for inspecting a wafer mounted on a wafer-mounting surface, characterized in that reflectance of at least a portion other than a portion for mounting the wafer of the wafer-mounting surface is smaller than reflectance of the wafer to be inspected, and particularly, smaller than reflectance of a circumferential end portion of the wafer.

In the chuck top of the present invention described above, preferably, the wafer-mounting surface has a chuck top conductive layer, and reflectance of at least a portion other than a portion for mounting the wafer of the chuck top conductive layer is smaller than reflectance of the wafer to be inspected, and particularly, smaller than reflectance of a circumferential end portion of the wafer. Preferably, the chuck top conductive layer is formed entirely on the wafer-mounting surface of the chuck top.

In the chuck top of the present invention described above, preferably, surface roughness Ra of at least a portion other than a portion for mounting the wafer of the wafer-mounting surface of the chuck top is at least 0.0001 μm and at most 0.05 μm.

The present invention also provides a wafer holder including the chuck top described above and a supporter supporting the chuck top, as well as a wafer prober including the chuck top described above.

According to the present invention, the wafer mounted on the wafer-mounting surface can be recognized reliably by a camera such as a CCD, and therefore, accurate registration of the wafer becomes possible and hence smooth inspection of the wafer can be preformed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a basic, specific example of a wafer holder in accordance with the present invention.

FIG. 2 is a schematic cross-sectional view showing a specific example of a heater body used in the wafer holder in accordance with the present invention.

FIG. 3 is a schematic plan view showing a specific example of a supporter in the wafer holder in accordance with the present invention.

FIGS. 4 and 5 are schematic plan views showing other specific examples of the supporter in the wafer holder in accordance with the present invention.

FIG. 6 is a schematic cross-sectional view showing another specific example of the wafer holder in accordance with the present invention.

FIG. 7 is a schematic cross-sectional view showing a portion around an electrode portion of the wafer holder in accordance with the present invention.

FIGS. 8 to 12 are schematic cross-sectional views showing other specific examples of the wafer holder in accordance with the present invention.

### DESCRIPTION OF THE PREFERRED EMBODIMENTS

Generally, when a wafer is inspected by a wafer prober, it is often the case that the wafer is heated, and therefore, provision of a heater such as a resistance heater body in a chuck top is common. The heat generated by the heater is transferred from the surface of chuck top to the wafer through conduction, convention or radiation. When the wafer-mounting surface of the chuck top has large surface roughness, heat transfer to the wafer is suppressed, while contact between the chuck top and the wafer becomes point-contact, resulting in portions where the chuck top and the wafer are not in contact with each other. The wafer temperature lowers at such portions, leading to a problem that accurate probing becomes impossible.

In view of the forgoing, conventionally, the surface of the chuck top is polished to a mirror finish, to improve close contact between the wafer and the chuck top. When the close contact between the wafer and the chuck top is improved, the chuck top surface comes to have higher reflectance, and as a result, difference from the reflectance of the wafer becomes extremely small. Consequently, recognition of the wafer by a camera such as a CCD fails more frequently.

Therefore, in the present invention, the reflectance of at least a portion other than the portion where the wafer is mounted of the wafer-mounting surface is made smaller than the reflectance of the wafer to be inspected, particularly, than the reflectance of a circumferential end of the wafer. As a result, an exposed surface of the chuck top on which the wafer is mounted comes to have reflectance different from that of the wafer, and hence, the wafer can surely be recognized by a camera such as a CCD. In the present invention, the reflectance of the entire wafer-mounting surface of the chuck top may be made smaller than the reflectance of the wafer to be inspected. Sometimes, a chuck top conductive layer is formed to ensure conduction to the wafer, on the wafer-mounting surface of the chuck top, and in this case also, the reflectance of at least a portion other than the portion where the wafer is mounted of the chuck top conductive layer should be made smaller than the reflectance of the wafer to be inspected, and particularly, smaller than the reflectance of the circumferential end of the wafer.

In the present invention, the reflectance of the wafer-mounting surface of the chuck top, the chuck top conductive layer and the wafer to be inspected may be measured by a method using an optical measuring instrument such as a spectroscope, for example, in accordance with JIS Z 8741.

In the present invention, the method of making the reflectance of at least a portion other than the portion where the wafer is mounted of the wafer-mounting surface of the chuck top (including examples having chuck top conductive layer formed thereon, same in the following) smaller than the reflectance of the wafer to be inspected may include a method of making the surface roughness Ra of at least a portion other than the portion where the wafer is mounted of the wafer-mounting surface larger than the surface roughness Ra of the wafer.

Preferable range of the surface roughness Ra is preferably adjusted dependent on the material of the wafer-mounting surface. Specifically, it is preferred that the surface roughness Ra of at least a portion other than the portion where the wafer is mounted of the wafer-mounting surface of the chuck top (when the chuck top conductive layer is formed, the surface of the chuck top conductive layer) is controlled in the range of 0.0001 to 0.05 μm. When the surface roughness Ra is smaller than 0.0001 μm, difference between the reflectance of the wafer-mounting surface and the reflectance of the wafer becomes small, and it becomes difficult to recognize the wafer by a camera such as a CCD. Specifically, a thin film circuit is formed on the wafer surface, and therefore, the wafer surface has extremely small surface roughness. Therefore, when surface roughness Ra of the portion other than the portion where the wafer is mounted on the wafer-mounting surface is smaller than 0.0001 μm, it becomes difficult to recognize the shape of the wafer when it is viewed with visible light. When the surface roughness exceeds 0.05 μm, the space between the wafer and the chuck top becomes large, and satisfactory close contact therebetween cannot be ensured, and therefore, it becomes difficult to reliably attain uniform temperature distribution over the wafer surface.

In the present invention, surface roughness Ra represents arithmetic mean deviation, of which detailed definition can be found, for example, in JIS B 0601.

As a method of controlling reflectance of the wafer-mounting surface of the chuck top described above, a method may be adopted in which the wafer-mounting surface of the chuck top (when the chuck top conductive layer is formed, the chuck top conductive layer) is polished to a target surface roughness Ra. By way of example, when the chuck top conductive layer is formed on the wafer-mounting surface of the chuck top, the chuck top conductive layer may be formed by plating or thermal spraying of metal such as nickel, or combination thereof. By buffing or polishing with diamond abrasive, SiC abrasive or alumina abrasive the thus formed chuck top conductive layer, the surface of the chuck top conductive layer can be finished to have the prescribed surface roughness.

It is preferred that the material of the wafer-mounting surface of the chuck top is other than silicon (Si). Typically, the wafer to be inspected is formed of Si, and therefore, when the wafer-mounting surface of the chuck top is formed of the same material Si, the boundary between the wafer and the chuck top would be indefinite, even when the surface roughness is in the above-described range. Therefore, it is preferred that the wafer-mounting surface of the chuck top is formed of a material including nickel, silver, gold or ceramics. When the wafer-mounting surface of the chuck top is formed of such a material and the wafer-mounting surface of the chuck top is adjusted to the surface roughness described above, the boundary between the chuck top surface and the wafer becomes more definite when monitored by a camera such as a CCD.

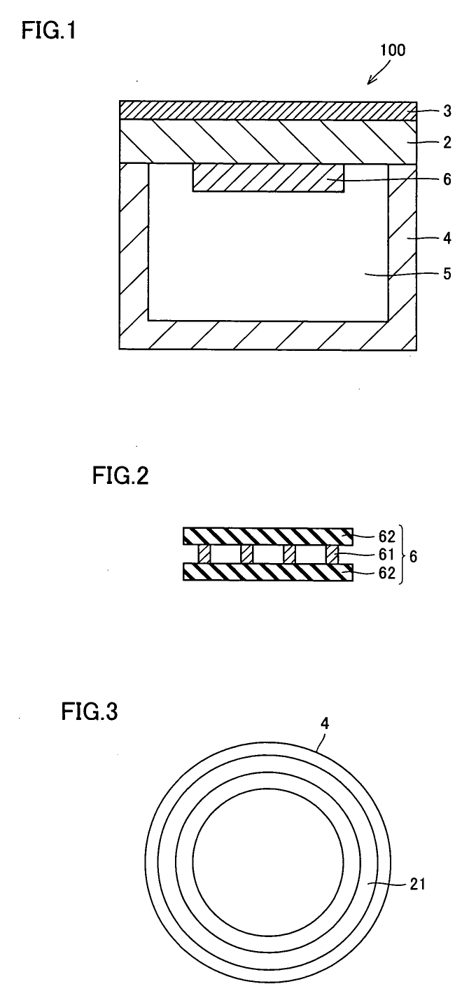

A basic form of the wafer holder with the chuck top in accordance with the present invention will be described with reference to FIG. 1. Wafer holder 100 has a chuck top 2 having a chuck top conductive layer 3, and a supporter 4 supporting chuck top 2, and has a space 5 at a portion between chuck top 2 and supporter 4. Supporter 4 having a hollow cylindrical portion with a bottom is preferred, as contact area between chuck top 2 and supporter 4 can be made small and space 5 can be formed easily.

When such space 5 is formed, what lies between chuck top 2 and supporter 4 is mostly an air layer, and hence, it follows that the wafer holder of the present invention has an efficient heat insulating structure. Further, here the wafer holder of the present invention has a hollow structure, and therefore, the weight can be reduced than when a common supporter of solid cylindrical shape is provided. The shape of space 5 is not specifically limited, and any shape that can suppress as much as possible the amount of cool air or heat generated at chuck top 2 to supporter 4 may be adopted.

It is preferred that chuck top 2 of the wafer holder in accordance with the present invention includes a heater body 6 for heating chuck top 2, as shown in FIG. 1. It is often the case recently that the wafer is heated to 100 to 200° C. for probing the semiconductor. When the heat of heater body 6 heating chuck top 2 is transferred to supporter 4, however, the heat would be transferred to a driving system provided below supporter 4, and because of difference in thermal expansion of metal components, machine accuracy would be deviated, possibly causing significant deterioration in flatness and parallelism of the wafer-mounting surface of chuck top 2. When the wafer holder of the present invention has the heat insulating structure described above, the flatness and parallelism would not significantly be deteriorated.

As the above-described heater body 6, one formed by sandwiching a resistance heater body 61 with an insulator 62 such as mica, as shown in FIG. 2, is preferred, as it has a simple structure. Metal material may be used for resistance heater body 61, and by way of example, nickel, stainless steel, silver, tungsten, molybdenum, chromium and an alloy of these may be used. Of these metals, stainless steel or nichrome is particularly preferred. Stainless steel and nichrome allow formation of a circuit pattern of resistance heater body with relatively high precision by a method such as etching, when it is processed to the shape of the heater body. Further, it is preferred because it is inexpensive, and is oxidation resistant and withstands use for a long period of time even when the temperature of use is high.

Insulator 62 sandwiching resistance heater body 61 is not specifically limited, and any heat-resistant insulator may be used. By way of example, mica mentioned above, silicone resin, epoxy resin, phenol resin or the like may be used. When an insulating resin is used as insulator 62 and resistance heater body 61 is sandwiched by insulator 62, filler may be dispersed in the resin, in order to transfer heat generated by resistance heater body 6 more smoothly to chuck top 2. The filler dispersed in the resin serves to increase thermal conductivity of the insulating resin such as silicone resin. Filler material is not specifically limited, provided that it does not have reactivity to the resin, and a substance such as boron nitride, aluminum nitride, alumina, silica or the like may be available. Heater body 6 may be fixed on the mounting portion by, for example, a mechanical method such as screw fixing.

In the wafer holder in accordance with the present invention, supporter 4 preferably has Young's modulus of at least 200 GPa, and more preferably at least 300 GPa. When Young's modulus of supporter 4 is smaller than 250 GPa, thickness of the bottom portion of supporter 4 cannot be made thin, and therefore, it is difficult to satisfactorily ensure volume of space 5, and hence good heat insulating effect would not be expected. Further, if a cooling module, which will be described later, is installed, it tends to be difficult to ensure a space for the cooling module. Supporter 4 having Young's modulus of 300 GPa or higher is particularly preferred, as the deformation of supporter 4 can significantly be reduced, allowing further reduction in size and weight of supporter 4.

In the present invention, Young's modulus may be measured, for example, by the pulse method or the flexural resonance method.

Supporter 4 preferably has thermal conductivity of at most 40 W/mK. When the thermal conductivity of supporter 4 exceeds 40 W/mK, the heat applied to chuck top 2 is easily transferred to supporter 4, possibly affecting the accuracy of the driving system. Recently, a temperature as high as 150° C. is required at the time of probing, and therefore, it is more preferred that supporter 4 has thermal conductivity of at most 10 W/mK, and thermal conductivity of at most 5 W/mK is particularly preferred. With the thermal conductivity of this range, the amount of heat transfer from supporter 4 to the driving system decreases significantly.

In the present invention, the thermal conductivity may be measured by a method such as laser flash method, using pelletized samples.

As a specific material that satisfies either Young's modulus or the thermal conductivity described above, mullite, alumina or a composite of mullite and alumina (mullite-alumina composite) is preferred. Mullite is preferred as it has low thermal conductivity and attains high heat insulating effect, and alumina is preferred as it has high Young's modulus and high rigidity. Mullite-alumina composite is generally preferred as the thermal conductivity is lower than alumina and Young's modulus is higher than mullite.

When supporter 4 has a hollow cylindrical shape with a bottom, it is preferred that the radial thickness of the cylindrical portion supporting chuck top 2 is at most 20 mm. When the radial thickness of the hollow cylindrical portion exceeds 20 mm, the amount of heat transferred from chuck top 2 to supporter 4 tends to increase. More preferably, the radial thickness of the cylindrical portion is at most 10 mm. When the radial thickness is smaller than 1 mm, supporter 4 tends to be deformed or damaged more easily by the pressure when the probe card is pressed to the wafer at the time of wafer inspection. Therefore, the radial thickness should preferably be at least 1 mm. The most preferable radial thickness of the hollow cylindrical portion is 10 to 15 mm. Further, that portion of the hollow cylindrical portion which is in contact with chuck top 2 should preferably have the radial thickness of 2 to 5 mm, as good balance between the strength and heat insulating characteristic of supporter 4 can be attained.

It is preferred that the height of hollow cylindrical portion of supporter 4 is at least 10 mm. When the height of the hollow cylindrical portion is lower than 1 mm, the pressure from probe card acts on chuck top 2 at the time of wafer inspection, and the pressure further propagates to supporter 4. As a result, the bottom portion of supporter 4 would deflect, possibly degrading flatness of chuck top 2.

The bottom portion of supporter 4 preferably has the thickness of at least 10 mm, and more preferably, 10 to 35 mm. When the thickness of the bottom portion of supporter 4 is smaller than 10 mm, the pressure from the probe card or heat of chuck top 2 would easily be transferred to supporter 4 at the time of wafer inspection, and the bottom of supporter 4 might be deflected by the pressure or might warp because of thermal expansion, possibly degrading flatness and parallelism of chuck top 2. The thickness of 35 mm or smaller is more suitable, as supporter 4 can be reduced in size.

In the present invention, it is possible to separate the hollow cylindrical portion and the bottom portion of supporter 4. In this case, the separated hollow cylindrical portion and the bottom portion come to have mutual contact interface. Therefore, it is preferred as the contact interface serves as a thermal resistance layer and once cuts off the heat transferred from chuck top 2 to supporter 4, and the temperature increase at the bottom portion is prevented.

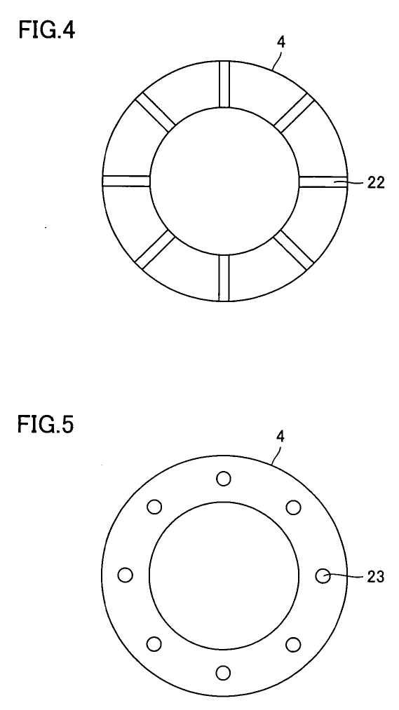

In the wafer holder of the present invention, a heat insulating structure may be formed on a support surface of chuck top 2, by reducing the contact area between chuck top 2 and supporter 4. More specifically, a notch may be formed on the support surface supporting chuck top 2 of supporter 4. By way of example, concentrical circular trench 21 such as shown in FIG. 3, or a plurality of radial trenches 22 arranged radially as shown in FIG. 4 may be formed. Alternatively, a number of projections may be formed on the support surface supporting chuck top 2 of supporter 4. Though the shapes of notches or projections are not specifically limited, it is preferred that the shape is in axial symmetry with respect to the central axis of supporter 4. If he shape of notches or projections is axially asymmetrical, it becomes impossible to uniformly disperse the pressure applied to chuck top 2, possibly resulting in deformation or damage to chuck top 2.

The heat insulating structure implemented by the notch and the like described above may be formed on a surface opposite to the wafer-mounting surface of chuck top 2. In that case, it is preferred that chuck top 2 has Young's modulus of at least 250 GPa. Specifically, as the pressure from the probe card acts on chuck top 2, the amount of deformation of chuck top 2 would inevitably increase if a notch or the like exists and Young's modulus is smaller than 250 GPa, possibly causing damage to the wafer or damage to chuck top 2 itself. Formation of the notch in supporter 4 described above is preferred, because such a problem can be avoided.

As another form of the heat insulating structure, a plurality of pillars 23 may be inserted and arranged between chuck top 2 and supporter 4, as shown in FIG. 5. It is preferred that pillars 23 are in uniform, concentrical arrangement or in a similar arrangement, and that the number is at least 8. Recently, wafer size has come to be increased to 8 to 12 inches, and therefore, if the number is smaller than 8, distance between pillars 23 to each other would be long, and when the pins of the probe card are pressed to the wafer mounted on chuck top 2, deflection would be more likely between the pillars 23.

When the plurality of pillars 23 are inserted and arranged between chuck top 2 and supporter 4, the heat insulating effect is better than in an integral type supporter 4, even when the contact area between chuck top 2 and pillars 23 and supporter 4 is the same. When the pillars 23 are inserted and arranged, two interfaces can be formed between chuck top 2 and pillar 23 and between pillar 23 and supporter 4. Therefore, as the interfaces serve as thermal resistance layer, the number of thermal resistance layers can be increased twice as much, whereby the heat generated in chuck top 2 can effectively be insulated. The shape of the pillars 23 is not specifically limited, and it may be a cylinder or it may be a triangular pole, a quadrangular pole or a polygonal pole with any polygon as a bottom surface.

As a material for pillars 23, one having thermal conductivity of at most 30 W/mK is preferred. When the thermal conductivity is higher than 30 W/mK, the heat insulating effect tends to decrease. As specific material of pillars 23, ceramics such as silicon nitride, mullite, mullite-alumina composite, steatite, or cordierite, stainless steel, glass (fiber), or heat resistant resin such as polyimide, epoxy or phenol, or a composite thereof may be used.

It is preferred that the surface roughness Ra at the contact portion between supporter 4 and chuck top 2 or pillar 23 is at least 0.1 μm. When the surface roughness Ra of this portion is smaller than 0.1 μm, contact area between supporter 4 and chuck top 2 or pillar 23 increases, and the gap between supporter 4 and chuck top 2 or pillar 23 becomes relatively smaller, so that the amount of heat transfer tends to increase as compared with the surface roughness Ra of 0.1 μm or larger. Though the upper limit of surface roughness Ra is not specifically limited, when the surface roughness Ra exceeds 5 μm, the cost for surface processing tends to increase, and therefore, surface roughness Ra of at most 5 μm is preferred. As for the method of adjusting the surface roughness Ra, polishing process or sand blasting may be performed.

In that case, it is preferred that conditions for polishing or sand blasting are optimized to maintain surface roughness Ra of at least 0.1 μm.

Further, it is preferred that the surface roughness Ra at the bottom portion of supporter 4 is at least 0.1 μm. This is also preferable, as in the example described above, as the amount of heat transfer to the driving system is reduced because of the rough surface roughness of the bottom portion of supporter 4. When it is possible to separate the bottom portion and the hollow cylindrical portion of supporter 4, as regards the surface roughness Ra of the contact portion between the bottom portion and the hollow cylindrical portion, it is preferred that surface roughness Ra of at least one of the bottom portion and the hollow cylindrical portion is at least 0.1 μm. When the surface roughness Ra is smaller than 0.1 μm, the effect of cutting off heat from the hollow cylindrical portion to the bottom portion would possibly be reduced. Further, it is also preferred that the surface roughness Ra at the contact surface between pillar 23 and supporter 4 or chuck top 2 is at least 0.1 μm. By similarly increasing the surface roughness of pillar 23, transfer of heat to the supporter 4 can be reduced.

As described above, by forming an interface between each of the members of the wafer holder and setting the surface roughness Ra at the interface to be at least 0.1 μm, the amount of heat transferred to the bottom portion of supporter 4 can efficiently be reduced, and as a result, power supply to the heater body 6 heating chuck top 2 can also be reduced.

Perpendicularity at a contact surface between an outer circumferential portion of the hollow cylindrical portion of supporter 4 and chuck top 2, at a contact surface between an outer circumferential portion of the hollow cylindrical portion of supporter 4 and pillar 23 and at a contact surface between an outer circumferential portion of pillar 23 and chuck top 2 should each preferably be at most 10 mm, with the measured length converted to 10 mm. With perpendicularity exceeding 10 mm, it is possible that when the pressure applied from chuck top 2 acts on the hollow cylindrical portion of supporter 4 or pillar 23, the hollow cylindrical portion or pillar 23 itself tends to deform more easily.

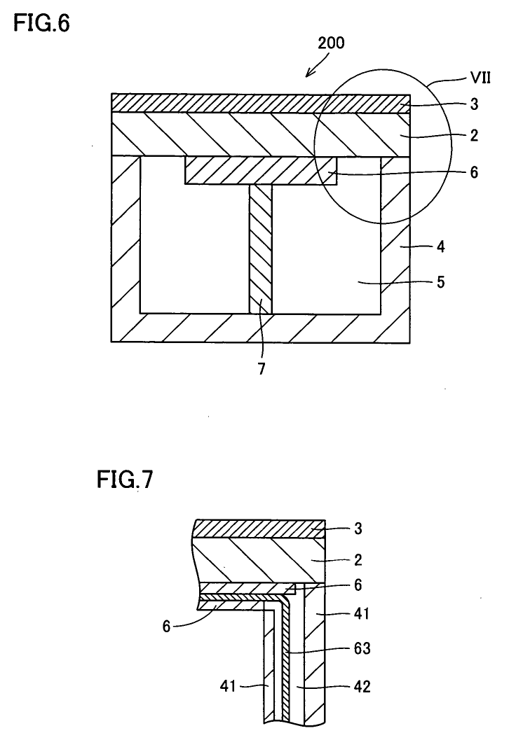

In the wafer holder of the present invention, it is preferred that a support rod 7 is provided near the central portion of supporter 4, as shown in wafer holder 200 of FIG. 6. Support rod 7 prevents deformation of chuck top 2, when the probe card is pressed on chuck top 2. It is preferred that the material of support rod 7 is the same as that of supporter 4. Supporter 4 and support rod 7 both thermally expand, as they receive heat from heater 6 heating chuck top 2. At this time, if supporter 4 and support rod 7 were formed of different materials, step would be generated between supporter 4 and support rod 7 due to difference in thermal expansion coefficient, and chuck top 2 would be deformed more easily.

Though the size of support rod 7 is not specifically limited, radial cross-sectional area should preferably be at least 10 cm². When the cross-sectional area is smaller than 10 cm², the effect of supporting chuck top 2 is insufficient, and support rod 7 tends to deform. When the cross-sectional area of support rod 7 exceeds 100 cm², the size of a cooling module to be inserted into the space 5 of supporter 4 would be smaller, as will be described later, and cooling efficiency would be degraded. Therefore, it is preferred that the cross-sectional area is at most 100 cm².

The shape of support rod 7 may be a cylinder, a triangular pole, a quadrangular pole or the like and it is not specifically limited. Though the method of fixing support rod 7 to supporter 4 is not specifically limited, brazing with an active metal, glass fixing, and screw fixing may be used and, among these methods, screw fixing is particularly preferred. Screw fixing facilitates attachment/detachment of support rod 7, and as heat treatment is not involved at the time of fixing, deformation of supporter 4 or support rod 7 by the heat treatment can be avoided.

As an exemplary structure around the portion feeding power to heater body 6 of the wafer holder in accordance with the present invention, a portion surrounded by a circle in FIG. 6 of wafer holder 200 is illustrated in enlargement in FIG. 7. It is preferred that the electrode portion for feeding power to heater body 6 attached to chuck top 2 has a through hole 42 formed in a hollow cylindrical portion 41 of supporter 4, and an electrode line 63 for feeding power or an electromagnetic shield electrode is inserted therein, as shown in FIG. 7. Here, the position for forming through hole 42 is preferably close to an inner circumferential portion of the hollow cylindrical portion 41 of supporter 4, that is, close to the central portion. When the formed through hole 42 is close to the outer circumference of hollow cylindrical portion 41, the strength of supporter 4 supporting with hollow cylindrical portion 41 tends to decrease because of the influence of the pressure of probe card, and supporter 4 tends to deform more easily near the through hole 42. It is noted that the electrode line and the through hole are not shown in figures other than FIG. 7, for the purpose of simplicity.

Further, it is preferred that a metal layer is formed on the surface of supporter 4 described above. Electromagnetic wave generated from heater body 6 for heating chuck top 2 becomes noise and affects wafer inspection, and formation of the metal layer on supporter 4 is preferred as it can intercept (shield) the electromagnetic wave. The method of forming the metal layer is not specifically limited, and by way of example, a conductive paste prepared by adding glass frit to metal powder of silver, gold, nickel or copper may be applied using a brush and burned.

As another method of forming the metal layer, metal such as aluminum or nickel may be thermally sprayed. Alternatively, the metal layer may be formed by plating. Combination of these methods is also possible. Specifically, metal such as nickel or the like may be plated after burning the conductive paste, or plating may be done after thermal spraying. Among these methods, plating or thermal spraying is particularly preferred. Plating is preferred, as it has high contact strength and allows formation of a highly reliable metal layer. Further, thermal spraying is preferred as it allows formation of the metal film at a relatively low cost.

As another method of forming the metal layer, a conductor may be provided on at least a part of the side surface of supporter 4. The conductor may be attached, for example, in a ring-shape on the side surface of supporter 4. The material used for the conductor is not specifically limited and, by way of example, stainless steel, nickel, aluminum or the like may be used.

When the ring-shaped conductor is to be attached on the side surface of supporter 4 as described above, by way of example, metal foil may be formed to a ring-shape of a size larger than the outer diameter of supporter 4, and attached on the side surface of supporter 4, whereby the conductor can be provided. Further, at the bottom surface of supporter 4, metal foil or a metal plate may be attached, and by connecting this to the metal foil or metal plate attached to the side surface of supporter 4, the effect of shielding the electromagnetic wave can further be enhanced. The metal foil or metal plate may be provided in space 5 inside the supporter 4, and by connecting this to the metal foil or metal plate attached to the side surface and the bottom surface of supporter 4, the effect of shielding the electromagnetic wave can be enhanced.

The method of attaching the conductor in the manner as described above is preferred, as the shield effect can be attained at a relatively low cost, as compared with the method of plating or applying conductive paste. Though the method of fixing the metal foil or metal plate on supporter 4 is not specifically limited, the metal foil or metal plate may be attached, by way of example, using metal screws. Further, the metal foil or the metal plates on the bottom surface and on the side surface may be integrated.

Further, it is preferred that a metal layer for intercepting (shielding) the electromagnetic wave is formed between heater body 6 heating chuck top 2 and chuck top 2. The electromagnetic shield layer may be formed by using the method of forming the metal layer on supporter 4 described above. By way of example, metal foil may be inserted between heater body 6 and chuck top 2. Though the metal foil used here is not specifically limited, foil of stainless steel, nickel or aluminum is preferred, as the temperature of heater body 6 increases to about 200° C.

Further, it is preferred that an insulating layer is provided between the electromagnetic shield layer and chuck top 2. The insulating layer serves to cut off noise that affects probing of the wafer, such as the electromagnetic wave or electric field generated at heater body 6 and the like. The noise particularly has significant influence on measurement of high-frequency characteristics of the wafer, and the noise does not have much influence on the measurement of normal electric characteristics. Though most of the noise generated at the heater body 6 is shielded by the electromagnetic shield layer, in terms of electric circuit, a capacitor is formed between chuck top conductive layer 3 formed on the wafer-mounting surface of chuck top 2 and the electromagnetic shield layer when chuck top 2 is an insulator, or between chuck top 2 itself and the electromagnetic shield layer when chuck top 2 is a conductor, and the capacitor may have an influence as a noise at the time of probing the wafer. When the insulating layer is formed between the electromagnetic shield layer and chuck top 2, the noise can be reduced.

When the insulating layer is formed, it is preferred that the resistance value of the insulating layer is at least 1×10⁷Ω. When the resistance value is smaller than 1×10⁷Ω, small current flows to chuck top conductive layer 3 because of the influence of heater body 6, which small current possibly becomes noise at the time of probing and affects probing. The resistance value of at least 1×10⁷Ω is preferred, as the small current can sufficiently be reduced not to affect probing. Recently, circuit patterns formed on wafers have been miniaturized, and therefore, it is preferred to reduce such noise as much as possible. When the resistance value of the insulating layer is set to at least 1×10¹⁰Ω, a structure of higher reliability can be attained.

Further, it is preferred that the dielectric constant of the insulating layer is at most 10. When the dielectric constant of the insulating layer exceeds 10, charges tend to be stored more easily between the electromagnetic shield layer sandwiching the insulating layer and chuck top 2, which might possibly be a cause of noise generation. Particularly, as the wafer circuits have been much miniaturized in these days as described above, it is preferable to reduce noise. Dielectric constant should preferably be at most 4 and more preferably at most 2. Setting small the dielectric constant is preferred, as the thickness of the insulating layer necessary for ensuring the insulation resistance value and the capacitance described above can be made thinner, and hence, thermal resistance posed by the insulating layer can be reduced.

Further, when chuck top 2 is an insulator, capacitance between chuck top conductive layer 3 and the electromagnetic shield layer, or when chuck top 2 is a conductor, the capacitance between chuck top 2 itself and the electromagnetic shield layer, should preferably be at most 5000 pF. When the capacitance exceeds 5000 pF, the influence of the insulating layer as a capacitor would be too large, possibly causing noise and affecting probing. As the wafer circuitry has been miniaturized as described above, capacitance of at most 1000 pF is particularly preferred, as good probing becomes possible.

As described above, by controlling the resistance value, dielectric constant and capacitance of the insulating layer, the influence of noise at the time of probing can significantly be reduced. The thickness of the insulating layer should preferably be at least 0.2 mm. In order to reduce the size of the device and to maintain good heat conduction from heater body 6 to chuck top 2, the thickness of the insulating layer should be small. When the thickness of the insulating layer becomes smaller than 0.2 mm, however, defects in the insulating layer itself or problems in durability would be generated. Ideal thickness of the insulating layer is at least 1 mm. Thickness of this range is preferred as it prevents the problem of durability and ensures good heat conduction from the heater body 6. Though there is no specific upper limit of the thickness of the insulating layer, preferably it is at most 10 mm. When the thickness exceeds 10 mm, though the noise cutting effect is good, the time of conduction of heat generated by heater body 6 to chuck top 2 and to the wafer becomes too long, and hence, it possibly becomes difficult to control the heating temperature. Though it depends on the conditions of probing, the upper limit of thickness of the insulating layer is preferably at most 5 mm, as temperature control is relatively easy.

Though there is no specific limit, the thermal conductivity of the insulating layer is preferably at least 0.5 W/mK, in order to realize good heat conduction from heater body 6 as described above. Thermal conductivity of at least 1 W/mK is preferred, as heat conduction is further improved.

The specific material for the insulating layer is not specifically limited, as long as it satisfies the characteristics described above and has heat resistance sufficient to withstand the probing temperature, and ceramics or resin may be used. When resin is used, filler may be dispersed in the resin. Of these, resin such as silicone resin or the silicone resin having filler dispersed therein, and ceramics such as alumina, may suitably be used. The filler dispersed in the resin serves to improve heat conduction of the resin. Any material having no reactivity to the resin may be used as the filler, and by way of example, substances such as boron nitride, aluminum nitride, alumina and silica may be available.

It is preferred that the diameter of the insulating layer is the same or larger than the area for forming the electromagnetic shield layer or heater body 6 described above. When the area for forming the insulating layer is smaller than the area for forming the electromagnetic shield layer or heater body 6, noise may possibly enter from a portion not covered with the insulating layer.

A specific example of the insulating layer will be described in the following. First, as the insulating layer, silicone resin having boron nitride dispersed therein may be used. The insulating layer has dielectric constant of 2. When the silicone resin having boron nitride dispersed therein is inserted as the insulating layer between the electromagnetic shield layer and the guard electrode and between the guard electrode and chuck top 2, and chuck top 2 corresponding to a 12-inch wafer is used, an insulating layer having the diameter of 300 mm, for example, may be formed. At this time, when the thickness of the insulating layer is set to 0.25 mm, capacitance of 5000 pF can be attained. When the thickness is set to 1.25 mm or more, capacitance of 1000 pF or lower can be attained. Volume resistivity of the insulating layer is 9×10¹⁵ Ω·cm, and therefore, when the diameter is 300 mm and the thickness is made at least 0.8 mm, the resistance value of at least 1×10¹²Ω can be attained. Further, the thermal conductivity of the material of the insulating layer is about 5 W/mK, and when the thickness, which can be selected in accordance with conditions of probing, is set to at least 1.25 mm, good capacitance and good resistance value can be attained.

It is preferred that warp of chuck top 2 is at most 30 μm. Generally, when the warp exceeds 30 μm, contact with a needle of the prober may possibly be biased at the time of probing, and evaluation of characteristics would fail, or erroneous determination of defects would be made because of the contact failure. Thus, it is possible that production yield is evaluated lower beyond necessity. Further, when the parallelism between the surface of the chuck top conductive layer 3 and the rear surface at the bottom portion of supporter 4 exceeds 30 μm, similar contact failure possibly occurs. Even when the warp and parallelism of chuck top 2 are at most 30 μm and satisfactory at a room temperature, it is not preferred from the same reasons as described above that at least one of the warp and parallelism exceeds 30 μm at the time of probing at 200° C. or −70° C. Specifically, it is preferred that warp and parallelism are at most 30 μm in the entire temperature range of probing.

The warp and parallelism may be measured using, for example, a three-dimensional measuring apparatus.

On the wafer-mounting surface of chuck top 2, chuck top conductive layer 3 may be formed. An object of forming chuck top conductive layer 3 is to protect chuck top 2 from corrosive gas, acid, alkali chemical, organic solvent or water commonly used in manufacturing semiconductors. Further, it also has a function of intercepting, between chuck top 2 and the wafer mounted on chuck top 2, electromagnetic noise from below the chuck top 2 and earthing.

It is preferred that chuck top conductive layer 3 is formed on the entire wafer-mounting surface of chuck top 2. This is advantageous as the reflectance of the wafer-mounting surface can easily be controlled and the function of protecting the chuck top and the function of earthing can be attained satisfactorily.

The method of forming chuck top conductive layer 3 is not specifically limited, and a method in which a conductive paste is applied by screen printing and then fired, vapor deposition or sputtering, thermal spraying and plating may be available. Among these, thermal spraying and plating are particularly preferred. These methods do not involve heat treatment at the time of forming the conductive layer, and therefore, warp of chuck top 2 caused by heat treatment can be avoided, and the cost is relatively low. Thus, such methods are advantageous in that an inexpensive conductive layer of superior characteristics can be formed.

Particularly, forming a thermally sprayed film on chuck top 2 and then forming a plating film further thereon is preferred. The thermally sprayed film has close contact with ceramics or metal ceramics better than a plated film, because the material thermally sprayed such as aluminum or nickel forms some compound such as oxide, nitride or oxynitride at the time of thermal spraying, and such compound reacts to the surface of chuck top 2, realizing firm contact. The thermally sprayed film, however, has low electric conductivity because it contains the compound mentioned above. In contrast, plating forms an almost pure metal film, and therefore, a conductive layer of superior electric conductivity can be formed, though contact strength with chuck top 2 is not as high as that of the thermally sprayed film. Therefore, forming the thermally sprayed film as a base and forming plating film thereon to form chuck top conductive layer 3 is particularly preferred, as the plated film and the thermally sprayed film are both metal and have good contact strength, and further, good electric conductivity can also be attained.

Further, it is preferred that the wafer-mounting surface of chuck top 2 (when chuck top conductive layer 3 is formed, chuck top conductive layer 3) has surface roughness Ra of at most 0.1 μm. When the surface roughness Ra exceeds 0.1 μm, the heat generated from a wafer itself having a high calorific value during probing for measuring the wafer could not be radiated from chuck top 2, and the wafer might be heated and possibly be broken by the heat. The surface roughness Ra of the wafer-mounting surface of chuck top 2 or of chuck top conductive layer 3 should more preferably be at most 0.02 μm, as more efficient heat radiation becomes possible.

When chuck top 2 is heated by heater body 6 for probing, for example, at 200° C., it is preferred that the temperature at a lower surface of supporter 4, that is, the rear surface of the bottom is at most 100° C. When the temperature of the lower surface of supporter 4 exceeds 100° C., the driving system provided below supporter 4 of the wafer prober is distorted because of difference in thermal expansion coefficient, and the accuracy would be degraded, possibly causing problems of positional deviation at the time of probing, warp or biased contact of the probe caused by lower parallelism. Thus, accurate wafer evaluation would be impossible. Further, when measurement is to be done at a room temperature after the measurement at an elevated temperature of 200° C., cooling from 200° C. to room temperature takes long time and hence, throughput would be decreased.

It is preferred that chuck top 2 has Young's modulus of at least 250 GPa. If Young's modulus of chuck top 2 is smaller than 250 GPa, chuck top 2 would be deflected by the load applied to chuck top 2 at the time of probing, and flatness and parallelism of the upper surface of chuck top 2 would possibly be degraded significantly. In that case, contact failure of probe pins occurs and accurate inspection becomes impossible, and further, the wafer might possibly be damaged. Therefore, Young's modulus of chuck top 2 is preferably at least 250 GPa and, more preferably, at least 300 GPa.

Chuck top 2 preferably has thermal conductivity of at least 15 W/mK. When the thermal conductivity of chuck top 2 is lower than 15 W/mK, temperature distribution of the wafer mounted on chuck top 2 would be deteriorated. When the thermal conductivity is not lower than 15 W/mK, thermal uniformity having no adverse influence on probing can be attained. As a material having such thermal conductivity, alumina having the purity of 99.5% (thermal conductivity of 30 W/mK) may be available. Thermal conductivity of at least 170 W/mK is more preferred, and materials having such thermal conductivity include aluminum nitride (170 W/mK) and Si—SiC composite (170 to 220 W/mK). With the thermal conductivity of this range, chuck top 2 having superior thermal uniformity can be obtained.

It is preferred that the thickness of chuck top 2 is at least 8 mm. When the thickness is smaller than 8 mm, chuck top 2 deflects by the load applied to chuck top 2 at the time of probing and flatness and parallelism of the upper surface of chuck top 2 are deteriorated significantly, causing contact failure of a probe pin and accurate measurement would be impossible. Further, the wafer might be damaged. Therefore, the thickness of chuck top 2 is preferably at least 8 mm, and more preferably at least 10 mm.

As the material for chuck top 2, metal-ceramics composite or ceramics is preferred. Preferred metal-ceramics composite material is either the composite material of aluminum and silicon carbide or composite material of silicon and silicon carbide, which has relatively high thermal conductivity and easily realizes thermal uniformity when the wafer is heated. Of these, composite of silicon and silicon carbide is particularly preferred, as it has particularly high Young's modulus and high thermal conductivity.

Further, as the composite materials described above are conductive, when the material of chuck top 2 is such composite as described above, heater body 6 may be formed through the method, for example, of forming an insulating layer through a method of thermal spraying or screen printing on a surface opposite to the wafer-mounting surface, and screen printing the conductive layer thereon, or forming the conductive layer in a prescribed shape through a method such as vapor deposition.

Alternatively, metal foil of stainless steel, nickel, molybdenum, tungsten or the like may be etched to form a prescribed pattern, to provide heater body 6. In this method, insulation from chuck top 2 may be attained by the method similar to that described above, or an insulating sheet may be inserted between chuck top 2 and heater body 6. This is preferable, as the insulating layer can be formed at considerably lower cost and in a simpler manner than the method described above. Resin available for this purpose includes, from the viewpoint of heat resistance, mica, epoxy resin, polyimide resin, phenol resin and silicone resin. Among these, mica is particularly preferable, as it has superior heat resistance and electric insulation, allows easy processing and is inexpensive.

Further, as the material of chuck top 2, it is relatively easy to use ceramics, as it does not necessitate formation of the insulating layer described above. As the method of forming heater body 6 in this case, methods similar to those described above may be adopted. Among ceramics, alumina, aluminum nitride, silicon nitride, mullite, and a composite material of alumina and mullite are preferred. These materials are particularly preferred as they have relatively high Young's modulus and not much deform even when pressed by the probe card. Of these, alumina is preferred as its cost is relatively low, and it has superior electric characteristics at a high temperature and, particularly, alumina having the purity of 99.6% or higher attains good insulation at high temperature. Specifically, at the time of sintering a substrate, in order to lower sintering temperature, an oxide of alkali-earth metal, silicon or the like is added to alumina, which lowers electric characteristics of pure alumina such as electric insulation at a high temperature. Therefore, purity of 99.6% or higher is preferred, and 99.9% or higher is more preferred.

It is preferred that chuck top 2 deflects at most by 30 μm when a load of 6.3 MPa is applied to chuck top 2. A large number of pins for inspecting the wafer press the wafer from the probe card, and therefore, the pressure also acts on chuck top 2, and chuck top 2 deflects to no small extent. When the amount of deflection at this time exceeds 30 μm, it becomes impossible to press the pins of the probe card uniformly onto the wafer, and inspection of the wafer might fail. More preferably, the amount of deflection when the pressure mentioned above is applied is at most 10 μm.

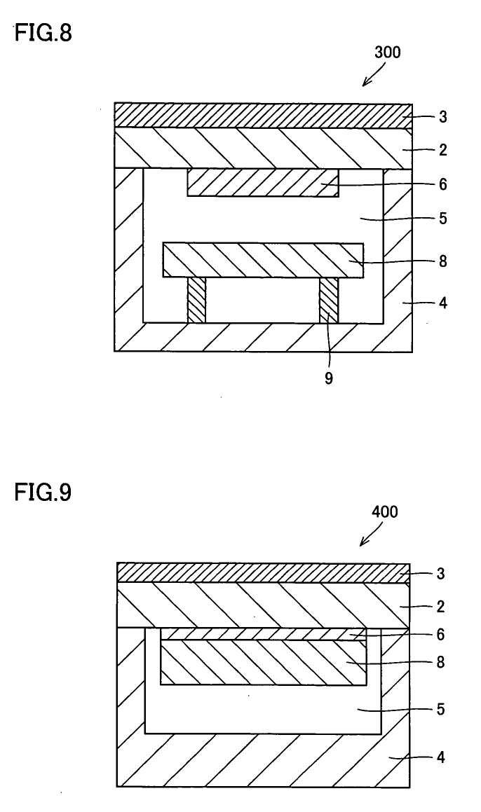

In the wafer holder of the present invention, a cooling module 8 may be provided inside the hollow cylindrical portion of supporter 4, as shown in wafer holder 300 of FIG. 8. When it becomes necessary to cool chuck top 2, cooling module 8 is brought into contact with chuck top 2 from the side opposite to the wafer-mounting surface and removes heat therefrom, so that chuck top 2 is cooled rapidly. At the time of heating chuck top 2, if cooling module 8 can be separated from chuck top 2, efficient temperature elevation of chuck top 2 becomes possible, and therefore, it is preferred that cooling module 8 is movable.

As a method of realizing mobile cooling module 8, an elevating mechanism 9 such as an air cylinder may be used as shown in FIG. 8. This approach is preferred as the cooling rate of chuck top 2 can significantly be improved and the throughput can be increased. According to this approach, cooling module 8 does not receive the pressure of probe card at all, and therefore, it is not deformed by the pressure. Further, this approach is preferred as the cooling performance is better than air cooling.

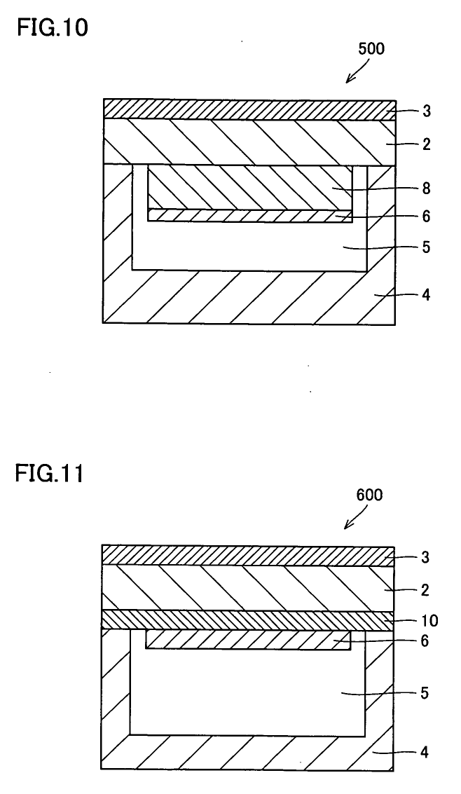

When the cooling rate of chuck top 2 is of high importance, cooling module 8 may be fixed on chuck top 2. As to the manner of fixing, heater body 6 of a structure in which a resistance heater body is sandwiched by an insulator may be provided on a surface opposite to the wafer-mounting surface of chuck top 2 and cooling module 8 may be fixed on the lower surface thereof, as shown in wafer holder 400 of FIG. 9. As another method, cooling module 8 may be directly attached to the surface opposite to the wafer-mounting surface of chuck top 2, and heater body 6 of a structure in which a resistance heater body is sandwiched by an insulator may be fixed on the lower surface thereof, as shown in wafer holder 500 of FIG. 10. No matter in which approach, the method of fixing cooling module 8 is not specifically limited and, by way of example, it may be fixed by a mechanical method such as screw fixing or clamping. When chuck top 2, cooling module 8 and heater body 6 are to be fixed together by screws, three or more screws, or six or more screws are preferred, as tight contact between each of chuck top 2, cooling module 8 and heater body 6 can be improved and cooling performance of chuck top 2 is further improved.

Further, cooling module 8 may be mounted in space 5 of supporter 4, or cooling module 8 may be mounted on supporter 4 and chuck top 2 may be mounted thereon. No matter which method is adopted, cooling rate can be increased as compared with the mobile example, as chuck top 2 and cooling module 8 are fixed together. Further, as cooling module 8 is mounted on supporter 4, the contact area of cooling module 8 with chuck top 2 is increased, and hence, chuck top 2 can more rapidly be cooled.

When cooling module 8 is fixed on chuck top 2, it is possible to increase the temperature without causing a coolant flow in cooling module 8. In that case, as the coolant does not flow through cooling module 8, the heat generated by heater unit 6 is not removed by the coolant and not go out of the system, and hence, more efficient heating becomes possible. In that case, however, it is still possible to cool chuck top 2 efficiently, by causing the coolant to flow through cooling module 8 at the time of cooling.

Further, the chuck top and the cooling module may be integrated. In that case, though the material of the chuck top and the cooling module used for integration is not specifically limited, it is preferred that the difference in thermal conductivity of the chuck top portion and the cooling module portion is as small as possible, and naturally, they should preferably be formed of the same material, as it is necessary to form a passage for the coolant in the cooling module.

As the material used here, ceramics or a composite of ceramics and metal described as the material for chuck top 2 above may be used. Here, chuck top conductive layer 3 is formed on the wafer-mounting surface, a passage for cooling the chuck top is formed on the opposite surface, and a substrate of the same material as the chuck top may be integrated by brazing or glass fixing. Naturally, the passage may be formed on the substrate to be bonded, or the passage may be formed on both substrates. Integration by screw fixing is also possible.

In this manner, by fully integrating the chuck top and the cooling module, it becomes possible to cool the chuck top even more rapidly, than when the cooling module is fixed on the chuck top.

Further, as the material of the integrated chuck top and cooling module, metal may be used. As compared with ceramics or ceramics-metal composite described above, metal allows easy processing and is inexpensive, and hence the passage can be formed easily. When metal is used as the material for the integrated chuck top, however, deflection may occur due to the pressure applied at the time of probing. In that case, deflection of chuck top 2 can be prevented by providing a substrate 10 for preventing deformation, at the surface opposite to the wafer-mounting surface of chuck top 2 integrated with the cooling module, as shown in wafer holder 600 of FIG. 11. It is preferred that substrate 10 for preventing deformation has Young's modulus of at least 250 GPa, as in the case of the chuck top, in order also to prevent deflection of the metal portion.

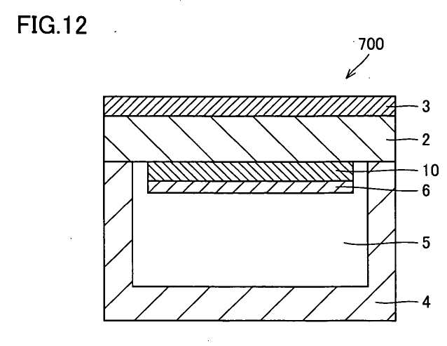

Substrate 10 for preventing deformation may be housed in space 5 of supporter 4, as shown in wafer holder 700 of FIG. 12. Further, substrate 10 for preventing deformation may be inserted between supporter 4 and chuck top 2 integrated with the cooling module. Substrate 10 for preventing deformation may be fixed on chuck top 2 by a mechanical method such as screw fixing, or by a method of blazing or glass fixing. When the chuck top and the cooling module are formed of metal and integrated, again, it is possible to heat and cool chuck top 2 more efficiently by not causing coolant to flow when chuck top 2 is heated or kept at a high temperature and causing the coolant to flow at the time of cooling.

In chuck top 2 formed of metal, chuck top conductive layer 3 may be newly formed on the surface of wafer-mounting side, if it is the case that the material of chuck top 2 is much susceptible to oxidation or alteration, or it does not have sufficiently high electric conductivity. As to the method, by applying oxidation resistant plating such as nickel, or by forming a conductive layer by the combination of thermal spraying and plating, and polishing the surface as the wafer-mounting surface, chuck top conductive layer 3 may be formed.

Further, even in such a structure as described above, an electromagnetic shield layer described above may be formed as needed. In that case, the insulated heater body 6 is covered with metal as described above, and may be fixed integrally on chuck top 2 by substrate 10 for preventing deformation.

As to the method of mounting chuck top 2 integrated with cooling module on supporter 4 when the chuck top integrated with cooling module is formed, the cooling module portion may be placed in space 5 formed in supporter 4, or as in the example in which chuck top 2 and cooling module 8 are fixed by screws, it may be mounted on supporter 4 at the cooling module portion.

Though the material of the cooling module is not specifically limited, aluminum, copper and an alloy of these are preferably used, because they have relatively high thermal conductivity and capable of removing heat quickly from the chuck top. It is also possible to use stainless steel, magnesium alloy, nickel or other metal materials. In order to add oxidation resistance to the cooling module, an oxidation resistant metal film such as nickel, gold or silver may be formed using the method of plating or thermal spraying.

Alternatively, ceramics may be used as the material for the cooling module. Though ceramics here is not specifically limited, aluminum nitride and silicon carbide are preferred as they have relatively high thermal conductivity and are capable of removing heat quickly from chuck top 2. Silicon nitride and aluminum oxynitride are preferred, as they have high mechanical strength and superior durability. Oxide ceramics such as alumina, cordierite and steatite are preferred as they are relatively inexpensive. As described above, various materials may be selected for the cooling module, and therefore, one may be selected in consideration of the intended use. Among these, nickel-plated aluminum or nickel-plated copper is particularly preferred, as it has superior oxidation resistance and high thermal conductivity and is relatively inexpensive.

Further, a coolant may be caused to flow in the cooling module. Causing the coolant flow is preferred, as the heat transferred from heater body 6 to the cooling module can quickly be removed and the cooling rate of heater body 6 can be improved. The coolant to be caused to flow in the cooling module is not specifically limited, and water or Fluorinert may be selected. Considering the magnitude of specific heat and cost, water is most preferable.

As a suitable example, two aluminum plates may be prepared as cooling plates, and the passage for the water flow may be formed by machine processing on one of the aluminum plates. In order to improve corrosion resistance and oxidation resistance, the entire surface is nickel-plated. The other aluminum plate is also nickel-plated, and the two aluminum plates are joined. At this time, a sealing member such as an O-ring is inserted around the passage, to prevent leakage of water, and the two aluminum plates are joined by screw fixing or welding.

Alternatively, two copper plates (oxygen-free copper) are prepared as the cooling plates, the passage through which water flows is formed by machine processing or the like on one of the copper plates, and the other copper plate and a pipe formed of stainless steel at an inlet of the coolant are simultaneously joined by brazing. In order to improve corrosion resistance and oxidation resistance of the joined cooling plates, the entire surface may be nickel-plated. As another approach, a pipe through which the coolant flows is attached to a cooling plate such as an aluminum plate or copper plate, whereby the cooling module may be formed. In this case, by forming a counter-sunk trench having a shape close to the cross-sectional shape of the pipe to realize close contact with the pipe, cooling efficiency can further be improved. Further, in order to improve tight contact between the cooling pipe and the cooling plate, thermally conductive resin, ceramics or the like may be inserted as an intervening layer.

As a still another approach, the cooling module may be formed by fixing a pipe, through which coolant may be caused to flow, to an aluminum or copper plate. Here, in order to ensure contact area between the pipe and the aluminum or copper plate, the aluminum or copper plate may be processed to have a trench of an approximately the same shape as the pipe, or a deformable substance such as resin may be inserted between the plate and the pipe. Alternatively, a flat-shaped portion may be formed on a portion of outer circumferential surface of the pipe and that portion may be fixed on the aluminum or copper plate. As to the method of fixing the plate and the pipe, screw fixing using a metal band, welding or brazing may be available.

As the coolant that is caused to flow through the cooling module, liquid such as water, Fluorinert or Galden, or gas such as nitrogen, air or helium may be used. The coolant to be used is not specifically limited, and it may be appropriately selected in consideration of the intended use.

The chuck top and the wafer holder in accordance with the present invention may be used suitably for heating and inspecting an object of processing such as a wafer, and by providing a driving system for moving the wafer holder, it may suitably be used as a wafer prober for inspecting electric characteristics of the wafer. Utilizing the characteristics such as high rigidity and high thermal conductivity, it may be applied, for example, to a handler apparatus or a tester apparatus, in addition to the wafer prober.

### EXAMPLES

Nine Si—SiC substrates having the diameter of 310 mm and the thickness of 15 mm were prepared. On the wafer-mounting surface of these Si—SiC substrates, a concentrical trench for vacuum chucking a wafer and a through hole were formed. Thereafter, the wafer-mounting surfaces of Samples 1 to 6 were nickel-plated, the wafer-mounting surface of Sample 7 was gold-plated, and the wafer-mounting surface of Sample 8 was silver-plated, and thus chuck top conductive layers 3 were formed. On the wafer-mounting surface of Sample 9, Si was vapor-deposited. The wafer-mounting surfaces of chuck-top conductive layers of Samples 1 to 8 and the wafer-mounting surface of Sample 9 were polished to have the overall warp amount of 10 μm and the values of surface roughness Ra as shown in Table 1 below, and thus, chuck tops 2 were provided.

On the other hand, nine mullite-alumina composite bodies of a pillar shape having the diameter of 310 mm and thickness of 40 mm were prepared as the material of supporter 4. One surface of these mullite-alumina composite bodies was counter-bored to have the inner diameter of 295 mm and the depth of 20 mm, and thus, supporters 4 of hollow cylindrical shape with a bottom having a space 5 therein were provided.

On each chuck top 2, stainless steel foil insulated with mica was attached as the electromagnetic shield layer, and heater body 6 sandwiched by mica was further attached. Heater body 6 was fabricated by etching stainless steel foil in a prescribed pattern. Further, a through hole was formed in supporter 4, and an electrode line for feeding power to heater body 6 was inserted. Then, the electromagnetic shield layer was formed by thermal spraying of aluminum, on side surfaces and bottom surfaces of these supporters 4.

Then, on supporter 4, chuck top 2 having heater body 6 and the electromagnetic shield layer attached was mounted, and thus, Samples 1 to 9 of wafer holders for wafer prober in which the wafer-mounting surface or the chuck top conductive layers have different surface roughness were fabricated.

It was confirmed that reflectance of the wafer-mounting surface or the chuck top conductive layer of Samples 1 to 9 of the wafer holder was smaller than the reflectance of the wafer used for inspection.

A wafer having the surface roughness Ra of 0.001 μm was mounted on the wafer-mounting surface (in Samples 1 to 8, chuck top conductive layer) of each wafer holder for wafer prober, heater body 6 was electrically conducted to heat the wafer to 150° C., and probing was done continuously for 24 hours. At that time, whether the wafer could be recognized or not by a CCD camera was tested. The results are also shown in Table 1.

TABLE 1

Wafer-mounting surface of chuck top

| | | Surface roughness | CCD camera |
|---|---|---|---|
| Sample | Material | Ra(μm) | recognition |
| 1 | Ni | 0.1 | D |
| 2 | Ni | 0.05 | B |
| 3 | Ni | 0.01 | A |
| 4 | Ni | 0.001 | A |
| 5 | Ni | 0.0001 | B |
| 6 | Ni | 0.00005 | E |
| 7 | Au | 0.01 | A |
| 8 | Ag | 0.01 | A |
| 9 | Si | 0.01 | C |

In Table 1 above, evaluation standards of CCD camera recognition are as follows.

A: All wafers could be recognized and inspection was satisfactory.

B: Most of the wafers could be recognized (recognition failure was 1% or lower).

C: Up to 10% of wafers could not be recognized.

D: Though wafers could be recognized, contact of wafer on the chuck top was not good during inspection.

E: 10% or more wafers could not be recognized.

Similar tests were conducted on samples having chuck top 2 formed alumina of 99.5% purity and formed of aluminum nitride containing 0.5% of yttria, and results similar to the above were obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A chuck top used for a wafer prober for inspecting a wafer mounted on a wafer-mounting surface, wherein reflectance of at least a portion other than a portion for mounting said wafer of said wafer-mounting surface is smaller than reflectance of the wafer to be inspected.

2. The chuck top according to claim 1, wherein surface roughness Ra of at least a portion other than the portion for mounting said wafer of said wafer-mounting surface is at least 0.0001 μm and at most 0.05 μm.

3. The chuck top according to claim 1, having a chuck top conductive layer on said wafer-mounting surface, wherein reflectance of at least a portion other than a portion for mounting said wafer of said chuck top conductive layer is smaller than reflectance of said wafer to be inspected.

4. The chuck top according to claim 3, wherein surface roughness Ra of at least a portion other than the portion for mounting said wafer of said wafer-mounting surface is at least 0.0001 μm and at most 0.05 μm.

5. The chuck top according to claim 3, wherein said chuck top conductive layer is formed entirely on the wafer-mounting surface of the chuck top.

6. The chuck top according to claim 5, wherein surface roughness Ra of at least a portion other than the portion for mounting said wafer of said wafer-mounting surface is at least 0.0001 μm and at most 0.051 μm.

7. A wafer holder comprising the chuck top according to claim 1 and a supporter supporting said chuck top.

8. A wafer prober, comprising the chuck top according to claim 1.
